(19) United States
(12) Patent Application Publication
(10) Pub. No.: US 2024/0206288 A1
(43) Pub. Date: Jun. 20, 2024

(54) LIGHT EMITTING DISPLAY DEVICE AND METHOD OF MANUFACTURING SAME

(71) Applicant: LG Display Co., Ltd., Seoul (KR)

(72) Inventors: Hyun KIM, Paju-si (KR); Da Yeon JEONG, Paju-si (KR); Chul Young JANG, Paju-si (KR); Sang Mo BYUN, Paju-si, Gyeonggi-do (KR)

(73) Assignee: LG Display Co., Ltd., Seoul (KR)

(21) Appl. No.: 18/538,388

(22) Filed: Dec. 13, 2023

(30) Foreign Application Priority Data
Dec. 15, 2022 (KR) 10-2022-0176322

(51) Int. Cl. H10K 59/80; H10K 59/12

(52) U.S. Cl. CPC H10K 59/8731; H10K 59/1201

(57) ABSTRACT

A light emitting display device includes a control pattern configured to control flow of a liquid material, thus defining an edge line of an organic encapsulation layer made of a liquid material and reducing a non-active area. The light emitting display device includes a control metal pattern configured to surround an active area at a non-active area and provided on a first inorganic encapsulation layer, an edge line pattern made of an organic material on the control metal pattern, and an organic encapsulation layer provided on the first inorganic encapsulation layer in an area inward from the control metal pattern.

### CROSS-REFERENCE TO RELATED APPLICATION

This application claims the priority of Korean Patent Application No. 10-2022-0176322, filed on Dec. 15, 2022, which is hereby incorporated by reference in its entirety.

### BACKGROUND

### Field of the Disclosure

The present disclosure relates to a display device, and more particularly to a light emitting display device, which includes a control pattern configured to control the position of a liquid encapsulation material, thus minimizing an outer area, and a method of manufacturing the same.

### Description of the Background

With development of information society, demand for display devices for displaying images in various forms is increasing.

A light emitting display device in which light emitting devices constitute pixels does not require a separate light source unit, and is thus favorable in view of slimness or flexibility and has an advantage of good color purity.

For example, a light emitting device includes two different electrodes and an emission layer therebetween, and when electrons generated from one electrode and holes generated from the remaining electrode are injected into the emission layer, the injected electrons and holes are combined to form excitons, and light emission occurs while the excitons thus formed fall from an excited state to a ground state.

Since a light emitting display device displays an image by light emitted from the emission layer, it is necessary to protect light emitting devices to prevent deterioration of the light emitting devices due to external factors. To this end, the light emitting display device includes an encapsulation structure.

### SUMMARY

To encapsulate light emitting devices, there is illustrated a thin film barrier in which inorganic and organic encapsulation layers are alternately formed. The organic encapsulation layer of the thin film barrier is formed by applying a liquid organic encapsulation material to a thickness sufficient to cover particles generated during processes. However, it is difficult to control spreading of the liquid material after application onto a flat surface. Hence, the light emitting display device may be configured such that the margin of the outer area is increased or a dam pattern having a predetermined thickness is further provided in the outer area in consideration of spreadability of the organic encapsulation material. However, even when the dam pattern is provided, in the case in which the width or height of the dam pattern is not sufficient, a material for forming an organic encapsulation layer may spread beyond the dam pattern, and in the case in which the number of dam patterns is increased, all of the area occupied by the dam patterns and the area required to maintain the space between the dam patterns are regarded as ineffective, and the ineffective area that is not used for actual display may increase, which is undesirable.

Accordingly, the present disclosure is directed to a light emitting display device and a method of manufacturing the same that substantially obviate one or more problems due to limitations and disadvantages described above.

The present disclosure provides a light emitting display device and a method of manufacturing the same, in which the light emitting display device includes a control pattern, thus guiding the area of a liquid organic material, and omits or reduces a dam pattern, thus minimizing a bezel area and maximizing an effective area.

Additional advantages and features of the disclosure will be set forth in part in the description which follows and in part will become apparent to those having ordinary skill in the art upon examination of the following or may be learned from practice of the disclosure. Other advantages of the disclosure may be realized and attained by the structure particularly pointed out in the written description and claims hereof as well as the appended drawings.

To achieve these and other advantages and in accordance with the purpose of the disclosure, as embodied and broadly described herein, a light emitting display device according to the present disclosure includes a control pattern configured to control flow of a liquid material, thus defining an edge line of an organic encapsulation layer made of the liquid material and reducing a non-active area.

A light emitting display device according to an aspect of the present disclosure includes a substrate having an active area including a plurality of sub-pixels and a non-active area surrounding the active area, a light emitting device provided to each of the plurality of sub-pixels, a first inorganic encapsulation layer configured to cover the light emitting device and provided in the active area and the non-active area, a control metal pattern configured to surround the active area in the non-active area and provided on the first inorganic encapsulation layer, an edge line pattern made of an organic material on the control metal pattern, an organic encapsulation layer provided on the first inorganic encapsulation layer in an area inward from the control metal pattern, and a second inorganic encapsulation layer configured to cover the organic encapsulation layer and the edge line pattern and provided to extend outward from the edge line pattern.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate aspects of the disclosure and together with the description serve to explain the principle of the disclosure.

In the drawings:

FIG. 1 is a plan view showing a light emitting display device according to an aspect of the present disclosure;

FIG. 2 is a cross-sectional view taken along line I-I′ of FIG. 1 according to a first aspect of the present disclosure;

FIGS. 3A and 3B are cross-sectional views showing a relationship between surface roughness and height of a control metal pattern of the light emitting display device according to the present disclosure;

FIG. 4 is a cross-sectional view taken along line I-I′ of FIG. 1 according to a second aspect of the present disclosure;

FIG. 5 is a cross-sectional view taken along line I-I′ of FIG. 1 according to a third aspect of the present disclosure;

FIG. 6 is a cross-sectional view taken along line I-I′ of FIG. 1 according to a fourth aspect of the present disclosure;

FIG. 7 is a plan view showing a light emitting display device according to a fifth aspect of the present disclosure; and

FIGS. 8A to 8E are cross-sectional views showing a process of manufacturing a light emitting display device according to an aspect of the present disclosure.

### DETAILED DESCRIPTION

Reference will now be made in detail to example aspects of the present disclosure, examples of which are illustrated in the accompanying drawings. Wherever possible, the same reference numbers will be used throughout the drawings to refer to the same or like parts, unless otherwise specified.

Advantages and features of the present disclosure, and a method of achieving the advantages and features will become apparent with reference to the example aspects described herein in detail together with the accompanying drawings. The present disclosure should not be construed as limited to the example aspects as disclosed below, and may be embodied in various different forms. Thus, these example aspects are set forth only to make the present disclosure sufficiently complete, and to assist those skilled in the art to fully understand the scope of the present disclosure. The protected scope of the present disclosure is defined by the claims and their equivalents.

In the following description of the present disclosure, where the detailed description of the relevant known steps, elements, functions, technologies, and configurations may unnecessarily obscure an important point of the present disclosure, a detailed description of such steps, elements, functions, technologies, and configurations maybe omitted. In addition, the names of elements used in the following description are selected in consideration of clarity of description of the specification, and may differ from the names of elements of actual products. Furthermore, in the following detailed description of the present disclosure, numerous specific details are set forth to provide a sufficiently thorough understanding of the present disclosure. However, it will be understood that the present disclosure may be practiced without these specific details. In other instances, known methods, procedures, components, and circuits have not been described in detail so as not to unnecessarily obscure aspects of the present disclosure.

The shapes, sizes, ratios, angles, numbers, and the like, which are illustrated in the drawings to describe various example aspects of the present disclosure are merely given by way of example. The disclosure is not limited to the illustrations in the drawings.

In the present specification, where terms such as “including,” “having,” “comprising,” and the like are used, one or more components may be added, unless the term, such as “only,” is used. As used herein, the term “and/or” includes a single associated listed item and any and all of the combinations of two or more of the associated listed items.

An expression such as “at least one of” when preceding a list of elements may modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example aspects of the present disclosure, where the positional relationship between two elements is described using terms, such as “on”, “above”, “under” and “next to”, at least one intervening element may be present between the two elements, unless “immediate(ly)” or “direct(ly)” or “close(ly) is used. It will be understood that when an element or layer is referred to as being “connected to”, or “coupled to” another element or layer, it may be directly connected to or coupled to the other element or layer, or one or more intervening elements or layers may be present.

In describing the various example aspects of the present disclosure, when terms such as “after,” “subsequently,” “next,” and “before,” are used to describe the temporal relationship between two events, another event may occur therebetween, unless a more limiting term, such as “just,” “immediate(ly),” or “directly” is used.

In describing the various example aspects of the present disclosure, terms such as “first” and “second” may be used to describe a variety of components. These terms aim to distinguish the same or similar components from one another and do not limit the components. Accordingly, throughout the specification, a “first” component may be the same as a “second” component within the technical concept of the present disclosure, unless specifically mentioned otherwise.

Features of various aspects of the present disclosure may be partially or overall coupled to or combined with each other, and may be variously inter-operated with each other and driven technically as those skilled in the art may sufficiently understand. The aspects of the present disclosure may be carried out independently from each other, or may be carried out together in a co-dependent relationship.

Hereinafter, a description will be provided with reference to the accompanying drawings.

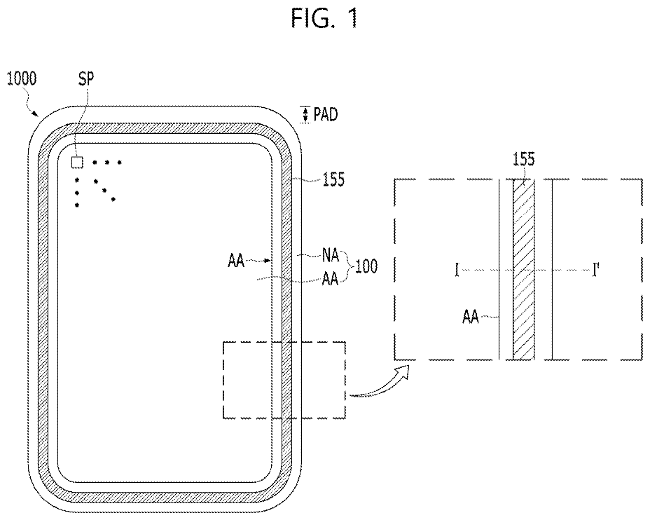

FIG. 1 is a plan view showing a light emitting display device according to an aspect of the present disclosure.

As shown in FIG. 1, the light emitting display device 1000 according to an aspect of the present disclosure includes a substrate 100 having an active area AA including a plurality of sub-pixels SP and a non-active area NA surrounding the outer perimeter of the active area AA.

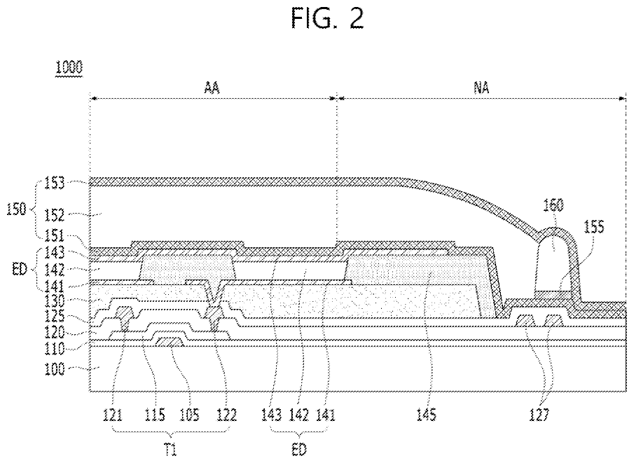

The substrate 100 includes an encapsulation structure 150 (FIG. 2) that protects a light emitting device ED (FIG. 2) provided to each of the sub-pixels SP in at least the active area AA. The encapsulation structure 150 may be provided in the entire active area AA and at least a part of the non-active area NA outside the active area AA.

As shown in FIG. 1, the light emitting display device 1000 according to an aspect of the present disclosure includes a control metal pattern 155 in the non-active area NA of the encapsulation structure 150. In the encapsulation structure that protects and encapsulates the active area AA, an organic encapsulation layer 152 (FIG. 2) is formed by applying a liquid material, and may have spreadability when applied due to liquid properties. The control metal pattern 155 according to the present disclosure functions to guide the organic encapsulation layer 152 made of a liquid material to be formed inward from the control metal pattern 155.

The control metal pattern 155 may be formed within the encapsulation structure 150 (FIG. 2), and particularly, may be located between inorganic encapsulation layers 151, 153 (FIG. 2) when viewed vertically.

A plurality of gate lines and a plurality of data lines crossing each other may be provided in the active area AA of the substrate 100, and sub-pixels SP may be disposed in each area where the lines cross each other. The configuration of the sub-pixels SP may be variously changed depending on the type of light emitting display device.

For example, the sub-pixels SP may be formed in a top emission manner, a bottom emission manner, or a dual emission manner, depending on the configuration thereof. The sub-pixels SP are units capable of emitting light of their own colors with or without a specific type of color filter. For example, the sub-pixels SP may include red, green, and blue sub-pixels. Alternatively, the sub-pixels SP may include, for example, red, blue, white, and green sub-pixels. The sub-pixels SP may have one or more different emission areas depending on light emitting characteristics. For example, sub-pixels emitting blue and other colors may have different emission areas.

One or more sub-pixels SP may constitute one unit pixel. For example, one unit pixel may include red, green, and blue sub-pixels, and the red, green, and blue sub-pixels may be repeatedly arranged. Alternatively, one unit pixel may include red, green, blue, and white sub-pixels, and the red, green, blue, and white sub-pixels may be repeatedly arranged, or the red, green, blue, and white sub-pixels may be arranged in a quad form.

In some aspects, the sub-pixels SP may include sub-pixels emitting at least two selected from among red light, green light, blue light, yellow light, magenta light, and cyan light. Also, the plurality of sub-pixels SP may emit their own colors with or without a specific type of color filter. However, the present disclosure is not necessarily limited thereto, and the color type, arrangement type, and arrangement order of the sub-pixels SP may vary depending on the light emitting characteristics, device lifespan, and device specifications.

In an aspect according to the present specification, the color type, arrangement type, arrangement order, etc. of the sub-pixels may be configured in various forms depending on the light emitting characteristics, device lifespan, device specifications, and the like, but the present disclosure is not limited thereto.

At least one side of the non-active area NA of the substrate 100 may include a pad portion PAD including a pad electrode. The pad electrode may be connected to the gate lines and the data lines of the active area AA through a link line. The link line may overlap the control metal pattern 155 surrounding the non-active area NA.

The encapsulation structure 150 may not be formed in the pad portion PAD. However, the present disclosure is not limited thereto, and when the encapsulation structure 150 is multilayered, some layers thereof may be formed in at least a part of the pad portion PAD.

Meanwhile, as shown in FIG. 1, the control metal pattern 155 may be formed in a closed loop shape in the non-active area NA. This serves to adjust the edge of the organic encapsulation layer 152 in an area inward from the control metal pattern 155. However, the control metal pattern 155 according to the present disclosure is not necessarily a closed loop. In some cases, the control metal pattern 155 may have an opening in at least a part of the substrate 100.

The control metal pattern 155 may have the same width in the non-active area NA along each side of the substrate 100. However, the present disclosure is not limited thereto, and the width of the control metal pattern 155 may vary depending on the side of the substrate 100. The width of the control metal pattern 155 may be increased on any side of the substrate 100 where the liquid material is excessive among sides of the substrate 100. For example, when the substrate 100 has the pad portion PAD at one side thereof as shown in FIG. 1, the non-active area NA corresponding to the side having the pad portion PAD requires a link line for connection between the pad electrode and lines such as the gate lines, the data lines, etc. in the active area AA. In addition, when the light emitting display device includes a gate-in-panel (GIP) circuit having a gate driver configured to drive gate lines by embedding the gate driver in the substrate 100, one side or both sides of the substrate adjacent to the gate lines may include the gate driver through the same process as a process of forming a thin film transistor of the active area AA. In addition, the non-active area NA of the substrate 100 may include a ground line. As described above, the non-active area NA of the substrate 100 may have a density difference on each side due to different lines and circuit types required for the pad portion and the gate driver, and accordingly, a surface step may be generated and thus spreadability of the liquid material may vary. In the light emitting display device according to the present disclosure, the width of the control metal pattern 155 is set to be different at a side having high step density and a side having low step density, whereby the organic encapsulation layer may be thoroughly positioned inward from the control metal pattern 155 regardless of areas even when the liquid material spreads.

In the active area AA, an image may be displayed by light emitted from each sub-pixel SP.

The pad portion PAD of the non-active area NA may be connected to an external printed circuit film or the like to receive an electrical signal from the outside.

Below is a specific description of a light emitting display device according to an aspect of the present disclosure with reference to cross-sectional views.

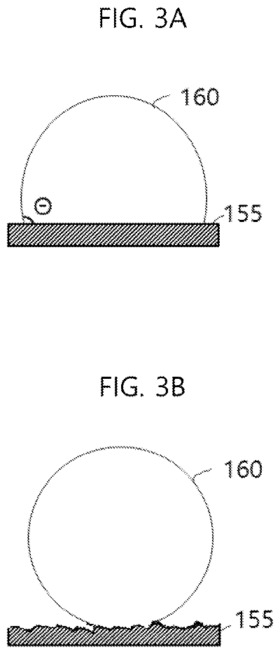

FIG. 2 is a cross-sectional view taken along line I-I′ of FIG. 1 according to a first aspect of the present disclosure, and FIGS. 3A and 3B are cross-sectional views showing a relationship between surface roughness and height of the control metal pattern of the light emitting display device according to the present disclosure.

As shown in FIG. 2, the light emitting display device 1000 according to the first aspect of the present disclosure includes a substrate 100 having an active area AA including a plurality of sub-pixels and a non-active area NA surrounding the active area, a light emitting device ED provided to each of the plurality of sub-pixels SP in the active area AA (FIG. 1), and an encapsulation structure 150 covering the light emitting device ED.

The encapsulation structure 150 of the light emitting display device 1000 according to the first aspect of the present disclosure includes a first inorganic encapsulation layer 151 provided in the active area AA and the non-active area NA, a control metal pattern 155 configured to surround the active area AA in the non-active area NA and provided on the first inorganic encapsulation layer 151, an edge line pattern 160 made of an organic material on the control metal pattern 155, an organic encapsulation layer 152 provided on the first inorganic encapsulation layer 151 in an area inward from the control metal pattern 155, and a second inorganic encapsulation layer 153 configured to cover the edge line pattern 160 and provided to extend outward from the edge line pattern 160.

The first inorganic encapsulation layer 151 and the second inorganic encapsulation layer 153 of the encapsulation structure 150 functionally prevent penetration of water or outside air introduced in a direction perpendicular thereto, and are formed thinly at a thickness of about 1 μm to 2 μm. The first and second inorganic encapsulation layers 151, 153 may be formed in a gaseous state by vacuum deposition. Moreover, the first and second inorganic encapsulation layers 151, 153 are formed throughout the entire substrate 100 except for the pad portion PAD.

The organic encapsulation layer 152 is formed to a high thickness sufficient to cover particles, etc. generated during processes. Since the organic encapsulation layer 152 may be more vulnerable to outside air and water than the first and second inorganic encapsulation layers 151, 153 due to material properties, it may be positioned inward relative to the first and second inorganic encapsulation layers 151, 153.

Since the organic encapsulation layer 152 needs to be formed thick enough to cover particles and large enough to cover at least the active area AA, it may be formed through spin coating using a liquid organic material. However, the liquid organic material may spread beyond a preset design area after coating (application), and thus, the light emitting display device according to the present disclosure is configured to include the control metal pattern 155 and the edge line pattern 160 on the control metal pattern 155 so that the liquid organic material is accommodated in an area inward from the control metal pattern 155.

In the process of spreading the liquid organic material after application, the edge line pattern 160 may serve as a kind of dam. Also, the organic encapsulation layer 152 formed by curing the liquid organic material may come into contact with the edge line pattern 160 and may be integrally formed therewith.

As a structure that prevents overflow of a liquid material encapsulation layer known to date, a multilayered dam is provided in the form of a planarization film that protects a thin film transistor array or a bank that defines the emission portion of each sub-pixel. However, such a dam structure alone has difficulty completely preventing overflow of the liquid material encapsulation layer, and accordingly, a plurality of dams is spaced apart from each other horizontally. The area occupied by the plurality of dam structures and the space between the dams cannot be used for display, which causes an increase in the non-active area. In addition, a multilayered dam may be formed by increasing the width of the planarization film dam pattern at the lower position to align the planarization film and the bank formed in different layers, increasing the area occupied by the dam pattern, which is undesirable.

The light emitting display device 1000 according to the present disclosure may obviate the dam structure and may solve problems occurring in a configuration having the dam structure.

In addition, the light emitting display device 1000 according to the present disclosure is configured such that the control metal pattern 155 and the edge line pattern 160, which control spreading of the liquid encapsulation material that is applied, are included in the encapsulation structure 150, thereby making it possible to control spreadability of the liquid material only with the configuration within the encapsulation structure without changing the outer region during the formation of the light emitting device or the thin film transistor array process. In addition, the edge line pattern 160 may be positioned within the width of the control metal pattern 155 due to surface tension of the control metal pattern 155, and the liquid organic encapsulation material may come into direct contact with the edge line pattern 160 during spreading thereof, and thus the organic encapsulation layer 152 and the edge line pattern 160 may be integrally formed with each other. Accordingly, the light emitting display device 1000 according to the present disclosure may obviate the area allocated to the area required for the dam structure in the non-active area (i.e., an outer area) NA and may minimize the non-active area.

The height and position of the edge line pattern 160 on the control metal pattern 155 are controlled due to surface tension of the control metal pattern 155.

The control metal pattern 155 of the light emitting display device 1000 according to the present disclosure functions to accommodate the liquid material and prevent the same from spreading due to surface characteristics thereof. This is deemed to be caused by surface tension occurring at the surface where the control metal pattern 155 and the liquid material come into contact with each other.

The surface tension at the surface where the control metal pattern 155 and the edge line pattern 160 are in contact with each other results from surface roughness of the control metal pattern 155 and a difference in physical properties between the control metal pattern 155 and the edge line pattern 160.

For example, when the edge line pattern 160 applied on the control metal pattern 155 is made of a hydrophobic organic material and the surface of the control metal pattern 155 is hydrophilic (opposite of hydrophobic), as shown in FIG. 3A, the edge line pattern 160 formed on the control metal pattern 155 having low roughness has a contact angle of 75° to 135°, does not deviate outside the control metal pattern 155, and remains in shape that rises on the surface of the control metal pattern 155.

Also, as shown in FIG. 3B, when the surface of the control metal pattern 155 has high roughness as well as when the edge line pattern 160 is made of a hydrophobic organic material and the surface of the control metal pattern 155 is hydrophilic (opposite of hydrophobic), the edge line pattern 160 made of the hydrophobic organic material on the control metal pattern 155 is more repelled from the surface of the control metal pattern 155 and has a large contact angle of 135° or more, and the edge line pattern 160 remains at a large thickness on the surface of the control metal pattern 155. Therefore, as shown in FIG. 3B, when the control metal pattern 155 and the edge line pattern 160 have opposite polarities and the control metal pattern 155 has high surface roughness, the thickness of the edge line pattern 160 may be increased compared to the case where the surface roughness of the control metal pattern 155 is low or the surface thereof is flat as shown in FIG. 3A.

In addition, even when the control metal pattern 155 is hydrophobic and the edge line pattern 160 is hydrophilic, the thickness of the edge line pattern 160 may be adjusted by controlling the surface roughness.

The thickness of the edge line pattern 160 rising on the control metal pattern 155 may be adjusted by making the surface roughness of the control metal pattern 155 greater than that of the surrounding first inorganic encapsulation layer 151.

Specifically, the height and width of the edge line pattern 160 according to the present disclosure may be adjusted by controlling surface roughness of the control metal pattern 155 and inducing a difference in physical properties between the control metal pattern 155 and the edge line pattern 160. The edge line pattern 160 is positioned within the width of the control metal pattern 155. In the light emitting display device according to the present disclosure, the area occupied by the edge line pattern 160 in the outer area NA is within the control metal pattern 155, and the control metal pattern 155 overlaps the area where a metal line 127 is located in the outer area NA, so that the outer area is not allocated for the area occupied by the control metal pattern 155. Therefore, the light emitting display device 1000 according to the present disclosure may obviate a dam pattern structure or the like which is separately required to prevent the liquid material from overflowing upon formation of the organic encapsulation layer 152, and also, the area allocated to the dam pattern structure or the margin area designed as the edge and space between the dam pattern and the organic encapsulation layer may be omitted, so that the outer area of the light emitting display device may be minimized.

The control metal pattern 155 according to the present disclosure remains within the encapsulation structure 150 in the light emitting display device. When viewed vertically, the control metal pattern 155 is positioned between the first inorganic encapsulation layer 151 and the second inorganic encapsulation layer 153, and is in contact with the upper and lower inorganic encapsulation layers 153, 151 and is capable of preventing water and outside air such as oxygen from entering the inside of the light emitting display device from the external lateral side.

In addition, the control metal pattern 155 may include, for example, a getter metal. Specifically, the getter metal, which has oxygen and water capturing capability, may be left behind in the light emitting display device, may prevent penetration of water and oxygen from the outside, may capture hydrogen and oxygen remaining in the light emitting display device, and may stabilize internal operation of the light emitting display device.

The getter metal may include at least one selected from among cerium, lanthanum, magnesium, barium, aluminum, zirconium, hafnium, titanium, tantalum, niobium, and thorium.

Table 1 below shows the gas captured by each component as a getter material and the capture capacity thereof. Here, the capture capacity is a capture capacity when the capture gas is in a molecular state, and becomes doubled when converted to atoms.

TABLE 1

| Getter material | Capture gas | Capture capacity (PaI/mg) |
|---|---|---|
| Aluminum (Al) | Oxygen | 1.00 |
| Barium (Ba) | Carbon dioxide | 0.69 |
| | Hydrogen | 11.50 |
| | Nitrogen | 1.26 |
| | Oxygen | 2.00 |
| Magnesium (Mg) | Oxygen | 2.70 |
| Rare earth element (Ce, La) | Carbon dioxide | 0.29 |
| | Hydrogen | 6.13 |
| | Nitrogen | 0.43 |
| | Oxygen | 2.80 |
| Titanium (Ti) | Hydrogen | 27.00 |
| | Nitrogen | 0.85 |
| | Oxygen | 4.40 |

The oxygen capture capacity of each getter material in Table 1 was confirmed. This refers to a function in which external water or internal water of the light emitting display device is captured by the control metal pattern 155. Water contains oxygen and hydrogen components. The getter material capable of capturing both oxygen and hydrogen is used for the control metal pattern 155, which means that the control metal pattern 155 may effectively capture water inside and outside the light emitting display device.

The getter materials shown in Table 1 are components included in metals or alloys that may be used in metals constituting thin film transistors of light emitting display devices, and patternability and reproducibility thereof have been confirmed. In addition to the getter materials shown in Table 1, other metals or elements may also be used for the control metal pattern 155 so long as they have oxygen and hydrogen capturing capability. For example, stainless materials such as zirconium, hafnium, etc. and getter materials such as tantalum, niobium, thorium, etc. each have oxygen and hydrogen capturing capability, so these also may be used for the control metal pattern 155.

The edge line pattern 160 on the control metal pattern 155 may include the same material as the organic encapsulation layer 152, but the present disclosure is not limited thereto. The edge line pattern 160 is made of, for example, a hydrophobic organic material, particularly a material capable of height control on the control metal pattern 155. The edge line pattern 160 is applied in a liquid phase during application, but is cured before formation of the organic encapsulation layer 152, thus enabling regional control of the edge portion of the organic encapsulation layer 152. The edge line pattern 160 may be made of the same or different material from the organic encapsulation layer 152. When the edge line pattern 160 and the organic encapsulation layer 152 are made of different materials, mixing of the two components is prevented after application, so that they may be cured together in a single curing process.

The height of the edge line pattern 160 is greater than or equal to 0.3 times the thickness of the organic encapsulation layer 152 and is less than or equal to the thickness of the organic encapsulation layer 152. When the height of the edge line pattern 160 is 0.3 to 1 times the thickness of the organic encapsulation layer 152, the edge line pattern 160 serves as a kind of fence upon spreading of the liquid material after application of the liquid material of the organic encapsulation layer 152, thus preventing the liquid material from overflowing the edge line pattern 160.

After application of the liquid material of the organic encapsulation layer 152, the curing process is performed again, whereby the organic encapsulation layer 152 may come into contact with the side of the edge line pattern 160 and may be integrally formed with the edge line pattern 160.

The organic encapsulation layer 152 and the edge line pattern 160 are made of an organic material, for example, acrylic resin, methacrylic resin, polyisoprene, vinyl resin, epoxy resin, urethane resin, cellulose resin, or perylene resin.

Each of the first and second inorganic encapsulation layers 151, 153 may be provided as a single inorganic layer or at least one thereof may be provided as a plurality of inorganic layers. For example, the first and second inorganic encapsulation layers 151, 153 may be formed of silicon nitride, aluminum nitride, zirconium nitride, titanium nitride, hafnium nitride, tantalum nitride, silicon oxide, aluminum oxide, titanium oxide, tin oxide, cerium oxide, silicon oxynitride (SiON), lithium fluoride, etc.

In the encapsulation structure 150, each of the first and second inorganic encapsulation layers 151, 153 and the organic encapsulation layer 152 may be formed of an insulating material, thus preventing interference during driving of the light emitting device ED and the thin film transistor T1 thereunder.

The light emitting display device according to the present disclosure is configured such that a light emitting device ED including an anode 141 and a cathode 143 facing each other and an intermediate layer 142 between the anode and the cathode is provided to each sub-pixel SP (FIG. 1).

The intermediate layer 142 includes an emission layer. In addition to the emission layer, the intermediate layer 142 may further include hole-related layers related to hole transport and hole injection under the emission layer and electron-related layers related to electron transport and electron injection on the emission layer. In some cases, the intermediate layer 142 may include a plurality of emission layers overlapping each other.

As shown in FIG. 2, the intermediate layer 142 may be provided between banks 145, but the light emitting display device according to the present disclosure is not limited thereto. At least one layer in the intermediate layer 142 may be integrally formed over the plurality of sub-pixels SP. For example, at least one layer selected from among the hole-related layers, the electron-related layers, and the emission layer may be continuously provided on the banks 145, as well as between the neighboring banks 145.

To control operation of the light emitting device ED for each sub-pixel, the sub-pixel SP further includes a thin film transistor T1 connected to the light emitting device ED.

The thin film transistor T1 includes a semiconductor layer 115, a gate electrode 105 that overlaps the channel region of the semiconductor layer 115 and includes a gate insulating film 110 interposed therebetween, and a first electrode 121 and a second electrode 122 connected to respective sides of the semiconductor layer 115.

The semiconductor layer 115 may be formed of at least one selected from among an oxide semiconductor, crystalline silicon, and amorphous silicon.

Also, the semiconductor layer 115 may further include a conductive layer between the first electrode 121 and the second electrode 122.

An interlayer insulating film 120 may be provided between the semiconductor layer 115 and the first and second electrodes 121, 122 except for portions where the semiconductor layer 115 and the first and second electrodes 121, 122 are directly connected to each other.

Each of the gate insulating film 110 and the interlayer insulating film 120 is formed of an inorganic insulating film. For example, the gate insulating film 110 and the interlayer insulating film 120 may be formed of an oxide film, a nitride film, an oxynitride film, or the like.

Although there is provided an example in which the gate electrode 105 is located at a lower position than the semiconductor layer 115, the thin film transistor T1 of the light emitting display device according to the present disclosure is not limited thereto. The gate electrode may be located at a higher position than the semiconductor layer, and may be located at the same layer as the first and second electrodes 121, 122 as necessary.

Meanwhile, each of the gate electrode 105 and the first and second electrodes 121, 122 may be formed in a single layer or multiple layers of any one or alloys thereof selected from the group consisting of copper (Cu), molybdenum (Mo), aluminum (Al), chromium (Cr), gold (Au), titanium (Ti), nickel (Ni), neodymium (Nd), tantalum (Ta), and tungsten (W). For example, when the gate electrode 105 and the first and second electrodes 121, 122 are provided in a single layer, they may be formed of any one or alloys thereof selected from the group consisting of molybdenum (Mo), aluminum (Al), chromium (Cr), gold (Au), titanium (Ti), nickel (Ni), neodymium (Nd), and copper (Cu). Also, when the gate electrode 105 and the first and second electrodes 121, 122 are formed in multiple layers, a double layer of molybdenum/aluminum-neodymium, molybdenum/aluminum, titanium/aluminum, or copper/molybdenum-titanium may be provided. Alternatively, the gate electrode 105 and the first and second electrodes 121, 122 may be provided in a triple layer of molybdenum/aluminum-neodymium/molybdenum, molybdenum/aluminum/molybdenum, titanium/aluminum/titanium, or molybdenum-titanium/copper/molybdenum-titanium. However, the present disclosure is not limited thereto, and the gate electrode 105 and the first and second electrodes 121, 122 may be provided in multiple layers made of any one or alloys thereof selected from the group consisting of molybdenum (Mo), aluminum (Al), chromium (Cr), gold (Au), titanium (Ti), nickel (Ni), neodymium (Nd), and copper (Cu).

One of the first electrode 121 and the second electrode 122 is a source electrode, and the remaining one is a drain electrode. The thin film transistor T1 functions as a driving thin film transistor that drives the light emitting device ED, and the sub-pixel SP may further include a thin film transistor such as a switching thin film transistor and/or a sensing thin film transistor in addition to the illustrated thin film transistor T1.

Also, the metal line 127 overlapping the control metal pattern 155 may be located at the same layer as any one of the metals forming the thin film transistor T1. The metal line 127 overlapping the control metal pattern 155 may be, for example, a metal included in a gate driver of a GIP structure or a link line connected to a pad electrode of a pad portion PAD (FIG. 1). Alternatively, the metal line 127 overlapping the control metal pattern 155 may be a power line or a ground line surrounding an edge of the active area AA.

A passivation film 125 and a planarization film 130 are provided on the thin film transistor T1 to protect the thin film transistor T1.

Also, the light emitting device ED may be provided on the planarization film 130.

The planarization film 130 and the passivation film 125 contain therein a connection hole exposing the second electrode 122, and the anode 141 is connected to the second electrode 122 through the connection hole and is formed on the planarization film 130. The anode 141 of the light emitting device ED and the second electrode 122 of the thin film transistor T1 may be electrically connected to each other through the connection hole provided in the planarization film 130 and the passivation film 125.

The light emitting device ED may have a bank 145 on the planarization film 130 to expose the anode 141 corresponding to the emission portion of each sub-pixel.

The anode 141 of the light emitting device ED is connected to the thin film transistor T1 of each sub-pixel and is formed for each sub-pixel, and the cathode 143 may be provided in common to the plurality of sub-pixels SP.

A capping layer may be further provided on the cathode 143 to increase light emission efficiency of the light emitting device ED and protect the light emitting device ED. The capping layer may be formed before the encapsulation structure and may be formed during a deposition process for forming the light emitting device ED.

Below is a description of a light emitting display device according to another aspect of the present disclosure.

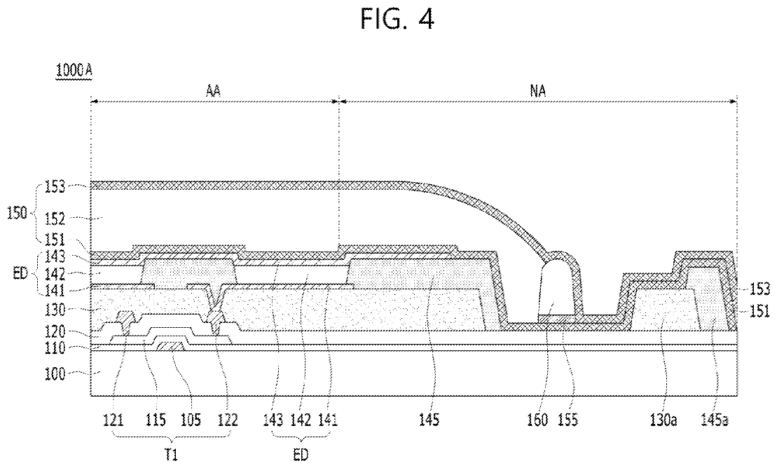

FIG. 4 is a cross-sectional view taken along line I-I′ of FIG. 1 according to a second aspect of the present disclosure.

As shown in FIG. 4, the light emitting display device 1000A according to the second aspect of the present disclosure further includes a first auxiliary protrusion 130a and a second auxiliary protrusion 145a outside the control metal pattern 155 compared to the light emitting display device 1000 according to the first aspect of the present disclosure shown in FIG. 2.

The first auxiliary protrusion 130a is formed in the same process as the planarization film 130, and the second auxiliary protrusion 145a is formed in the same process as the bank 145.

An overlapping portion between the first and second auxiliary protrusions 130a, 145a may be provided closer to the outer edge of the substrate 100. In the light emitting display device 1000A according to the second aspect of the present disclosure, an accommodation space that receives the liquid material is provided between the edge line pattern 160 and the first and second auxiliary protrusions 130a, 145a. As such, in the process of forming the organic encapsulation layer 152, even when overflow of the liquid material beyond the edge line pattern 160 occurs in some areas, the liquid material remains partially in the accommodation space between the edge line pattern 160 and the first and second auxiliary protrusions 130a, 145a. The liquid material in the accommodating space between the edge line pattern 160 and the first and second auxiliary protrusions 130a, 145a may finally be separated from the organic encapsulation layer 152 that is integrated with the edge line pattern 160.

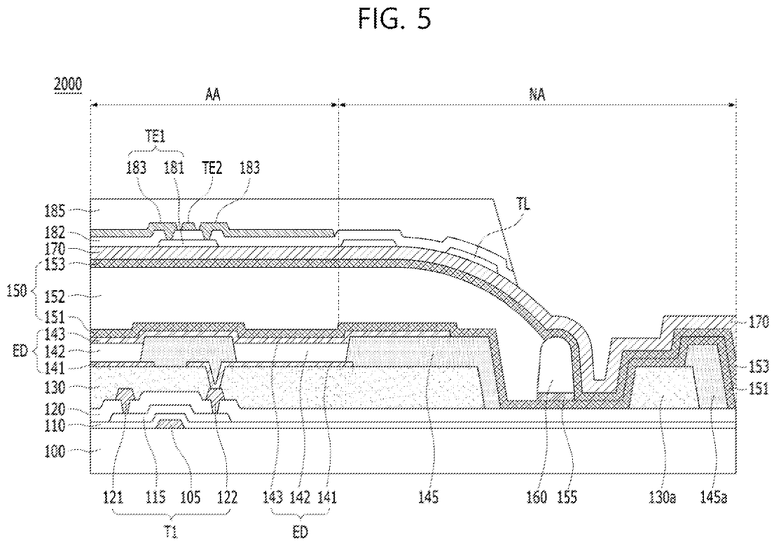

FIG. 5 is a cross-sectional view taken along line I-I′ of FIG. 1 according to a third aspect of the present disclosure.

As shown in FIG. 5, the light emitting display device 2000 according to the third aspect of the present disclosure is different in view of further including first and second touch electrodes TE1, TE2 on an encapsulation structure 150. In the light emitting display device 2000 in which the first and second touch electrodes TE1, TE2 are provided on the encapsulation structure 150, the touch position may be detected by sensing a change in capacitance in the first touch electrode TE1 and the second touch electrode TE2 depending on the user's touch.

The first and second touch electrodes TE1, TE2 may be configured to cross each other.

The first touch electrode TE1 may include a plurality of first touch electrode patterns 183 spaced apart from each other and a bridge electrode 181 electrically connecting the adjacent first touch electrode patterns 183 to each other. A touch intermediate insulating film 182 may be further provided between the bridge electrode 181 and the first touch electrode patterns 183, except for connection portions between the bridge electrode 181 and the first touch electrode patterns 183.

A touch buffer layer 170 may be further provided between the encapsulation structure 150 and the first and second touch electrodes TE1, TE2, and the bridge electrode 181 may be positioned on the touch buffer layer 170.

The plurality of first touch electrode patterns 183 of the first touch electrode TE1 and the second touch electrode TE2 may be positioned on the same layer. For example, the plurality of first touch electrode patterns 183 of the first touch electrode TE1 and the second touch electrode TE2 may be positioned on the touch intermediate insulating film 182.

A touch link line TL may be further provided to the same layer as the bridge electrode 181, and the touch link line TL may be connected to a touch pad portion (not shown) provided in a part of the non-active area NA of the substrate 100.

The first and second touch electrodes TE1, TE2 may be protected by a touch passivation film 185.

The light emitting display device 2000 according to the present disclosure has a control metal pattern 155 and an edge line pattern 160 in a non-active area NA, and in a configuration including first and second touch electrodes TE1, TE2 for touch sensing, any one insulating film selected from among the touch buffer layer 170, the touch intermediate insulating film 182, and the touch passivation film 185 may overlap the control metal pattern 155 and the edge line pattern 160.

Also, in a modification of the light emitting display device according to the third aspect of the present disclosure, the first and second auxiliary protrusions 130a, 145a may be omitted, and the non-active area NA may be further reduced.

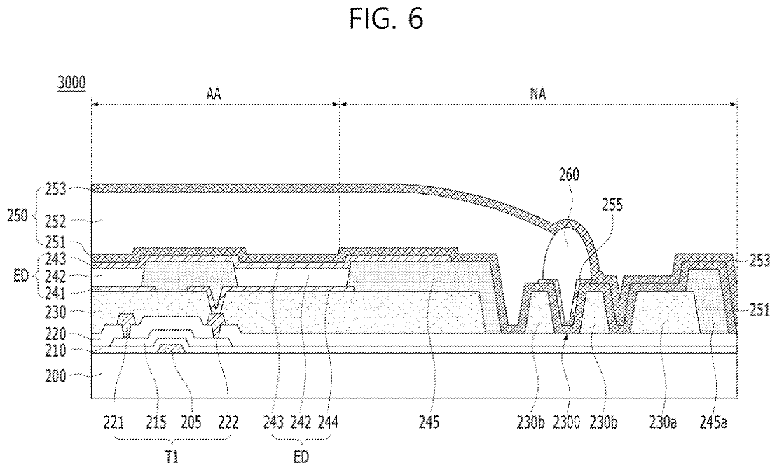

FIG. 6 is a cross-sectional view taken along line I-I′ of FIG. 1 according to a fourth aspect of the present disclosure.

As shown in FIG. 6, the light emitting display device 3000 according to the fourth aspect of the present disclosure is configured such that a concave-convex structure including a plurality of protrusions 230b and a flat 2300 between the protrusions 230b is further provided to the edge portion of an organic encapsulation layer 252.

As such, the first inorganic encapsulation layer 251 of the encapsulation structure 250 is also formed on the concave-convex structure along the surface of the protrusions 230b and the flat 2300 between the protrusions 230b.

Here, the first inorganic encapsulation layer 251 is thinner than the protrusions 230b, and the first inorganic encapsulation layer 251 is formed along the step between the protrusions 230b and the flat 2300.

Moreover, a control metal pattern 255 positioned on the first inorganic encapsulation layer 251 may be thinner than the first inorganic encapsulation layer 251, and the control metal pattern 255 may also be formed along the step of the concave-convex structure.

An edge line pattern 260 formed after the control metal pattern 255 is provided in the accommodation space of the concave-convex structure, and may be provided to an area where the control metal pattern 255 is located due to surface tension of the control metal pattern 255. In the light emitting display device according to the fourth aspect of the present disclosure, even when the control metal pattern 255 is provided at a small width of the non-active area NA of the substrate 200 due to the presence of the concave-convex structure, the contact surface area thereof with the edge line pattern 260 may be increased, thus further improving the effect of minimizing the non-active area NA.

The light emitting display device according to the fourth aspect of the present disclosure may include a first auxiliary protrusion 230a at the same layer as the planarization film 230 and a second auxiliary protrusion 245a at the same layer as the bank 245, spaced apart from the protrusions 230b and provided to the outer edge of the substrate 200.

In a light emitting display device according to another aspect of the present disclosure, either or both of the first auxiliary protrusion 230a and the second auxiliary protrusion 245a may be omitted. When the first or second auxiliary protrusion 230a, 245a is omitted, the non-active area may be reduced by the omitted area.

As shown in FIG. 6, in the encapsulation structure 250, each of the first and second inorganic encapsulation layers 251, 253 and the organic encapsulation layer 252 is formed of an insulating material, thus preventing interference during driving of the light emitting device ED and the thin film transistor T1 thereunder.

In addition, as shown in FIG. 6, the light emitting display device according to the present disclosure is configured such that a light emitting device ED including an anode 241 and a cathode 243 facing each other and an intermediate layer 242 between the anode and the cathode is provided to each sub-pixel SP (FIG. 1).

An intermediate layer 242 may be provided between banks 245, but the light emitting display device according to the present disclosure is not limited thereto. At least one layer in the intermediate layer 242 may be integrally formed over the plurality of sub-pixels SP. For example, at least one layer selected from among the hole-related layers, the electron-related layers, and the emission layer may be continuously provided on the banks 245, as well as between the neighboring banks 245.

In addition, the thin film transistor T1 includes a semiconductor layer 215, a gate electrode 205 that overlaps the channel region of the semiconductor layer 215 and includes a gate insulating film 210 interposed therebetween, and a first electrode 221 and a second electrode 222 connected to respective sides of the semiconductor layer 215.

A planarization film 230 protecting the thin film transistor T1 is further provided on the thin film transistor T1.

Each of the gate insulating film 210 and the interlayer insulating film 220 is formed of an inorganic insulating film. For example, the gate insulating film 210 and the interlayer insulating film 220 may be formed of an oxide film, a nitride film, an oxynitride film, or the like.

Also, the planarization film 230 is formed of an organic insulating material to the extent that the surface may be planarized, and may be made of at least one material selected from among organic materials such as photo acryl, polyimide, benzocyclobutene resin, and acrylate resin.

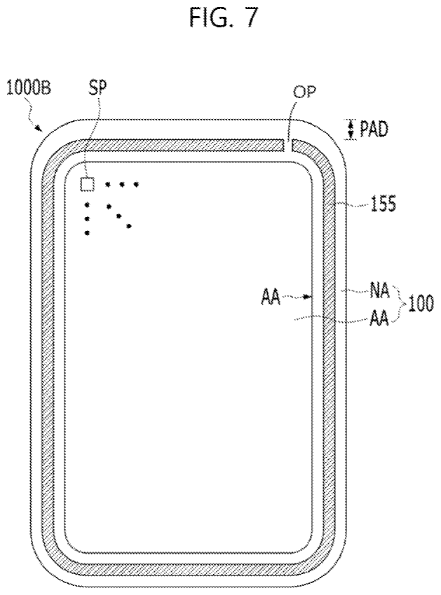

FIG. 7 is a plan view showing a light emitting display device according to a fifth aspect of the present disclosure.

As shown in FIG. 7, the light emitting display device 1000B according to the fifth aspect of the present disclosure includes an opening OP in at least a part of the control metal pattern 155.

When the liquid organic encapsulation material is applied under a condition that the control metal pattern 155 is provided and the edge line pattern 160 is formed on the control metal pattern 155 as shown in FIG. 2, excess liquid material is allowed to escape through the opening OP, thereby preventing the liquid material from spreading beyond the control metal pattern 155 in other areas. Excess organic encapsulation material escaping out of the opening OP may be selectively removed through post-processing.

Below is a description of a method of manufacturing a light emitting display device according to the present disclosure.

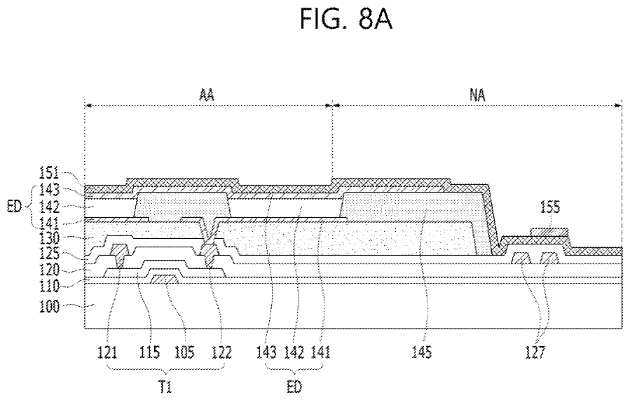

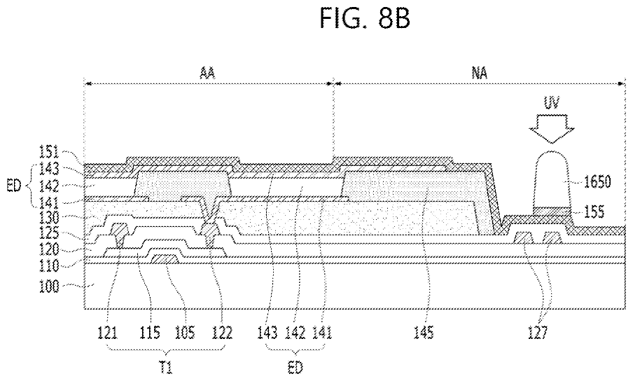

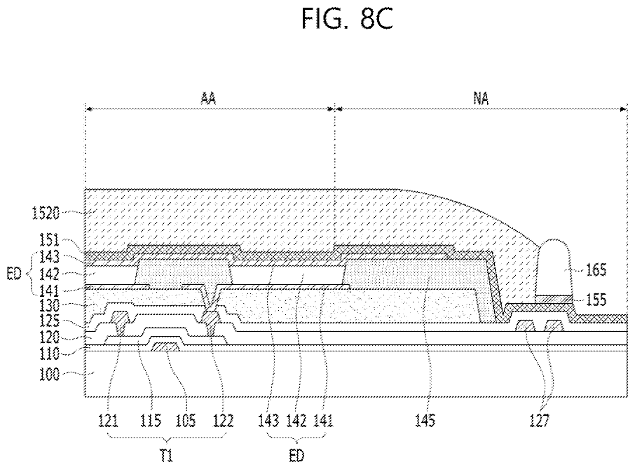

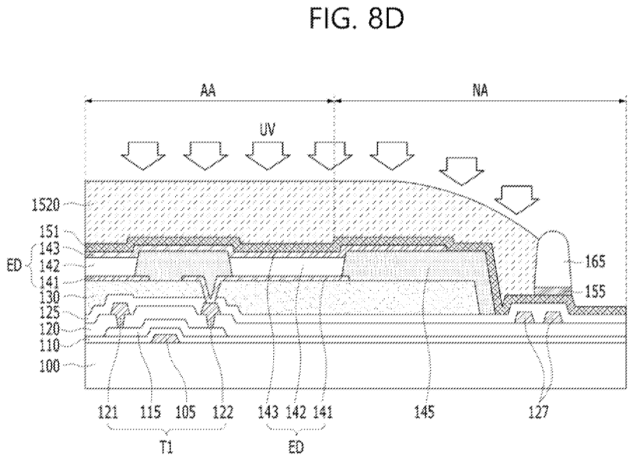

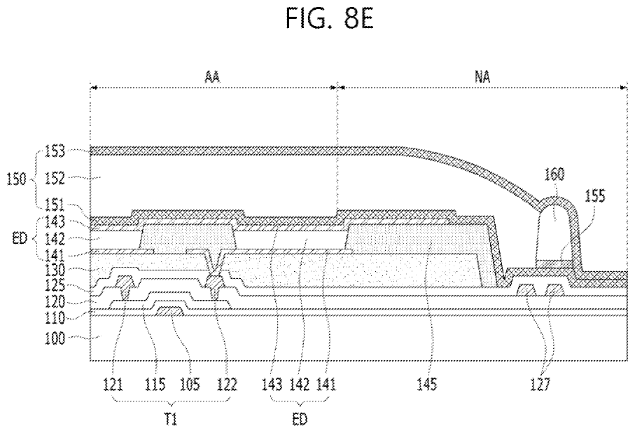

FIGS. 8A to 8E are cross-sectional views showing a process of manufacturing a light emitting display device according to an aspect of the present disclosure.

As shown in FIG. 8A, a substrate 100 having an active area AA including a plurality of sub-pixels and a non-active area NA surrounding the active area is prepared.

A thin film transistor T1 is formed in each sub-pixel.

In the process of forming the thin film transistor T1, a metal line 127 is formed in the same layer as at least one metal 105, 121, 122 constituting the thin film transistor T1 in the non-active area NA.

Next, a passivation film 125 and a planarization film 130 are sequentially formed.

A connection hole through which an upper portion of the second electrode 122 of the thin film transistor T1 is exposed is formed by selectively removing the passivation film 125 and the planarization film 130.

When the connection hole is formed, the first auxiliary protrusion 130a, 230a in FIGS. 4 to 6 may be patterned and formed with a material for the planarization film 130, 230. Also, the protrusions 230b of FIG. 6 may be formed between the planarization film 230 and the first auxiliary protrusion 230a.

Next, an anode component is formed on the entire surface of the planarization film 130 and then selectively removed, thus forming an anode 141 that is connected to the second electrode 122 through the connection hole in the passivation film 125 and the planarization film 130 and classified for each sub-pixel.

A bank 145 is formed to expose the emission portion of the anode 141. The bank 145 may extend from the edge of the active area AA to a part of the non-active area NA. The second auxiliary protrusion 145a, 245a in FIGS. 4 to 6 may be further formed in the same process as the process of forming the bank 145. In some cases, the protrusion 230b of FIG. 6 may be formed of a material for the bank 245.

Next, an intermediate layer 142 and a cathode 143 are formed.

The anode 141, the intermediate layer 142, and the cathode 143 stacked for each sub-pixel form a light emitting device ED.

After completion of formation of the light emitting device ED, an encapsulation structure protecting the light emitting device ED is formed.

Specifically, a first inorganic encapsulation layer 151 is formed.

A control metal pattern 155 is formed on the first inorganic encapsulation layer 151 in a part of the non-active area NA spaced apart from the active area AA. The control metal pattern 155 may overlap the metal line 127.

As shown in FIG. 8B, using surface tension of the surface in contact with the control metal pattern 155, an organic material 1650 is formed within a width of the control metal pattern 155 on the control metal pattern 155. The organic material 1650 is formed to a thickness 0.3 to 1 times the thickness of the organic encapsulation layer to be formed.

Next, the organic material 1650 is cured through UV irradiation, thus forming an edge line pattern 165 as shown in FIG. 8C.

Next, as shown in FIG. 8C, a liquid organic material 1520 is applied to an area inward from the control metal pattern 155. As such, the edge line pattern 165 serves as a barrier for the liquid organic material 1520 and thus prevents the liquid organic material 1520 from spreading beyond the edge line pattern 165.

Next, as shown in FIG. 8D, the liquid organic material 1520 is cured through UV irradiation, thus forming a solid organic encapsulation layer 152 as shown in FIG. 8E.

Next, a second inorganic encapsulation layer 153 is formed on the organic encapsulation layer 152.

The second inorganic encapsulation layer 153 located at the upper position covers the organic encapsulation layer 152 and the edge line pattern 160 and is provided to extend outward from the edge line pattern 160.

Therefore, the upper and outer portions of the edge line pattern 160 are covered by the second inorganic encapsulation layer 153, and the inner portion of the edge line pattern 160 is in contact with the organic encapsulation layer 152 and is integrated therewith, and the lower surface of the edge line pattern 160 is in contact with the upper surface of the control metal pattern 155.

In the light emitting display device according to the present disclosure and the method of manufacturing the same, before application of the liquid organic encapsulation material, the control metal pattern 155 is provided and the edge line pattern is formed on the control metal pattern, and thus the organic encapsulation layer 152 may be guided inward from the control metal pattern 155 that controls the edge line in the process of applying the liquid organic encapsulation material.

Also, in the light emitting display device according to the present disclosure and the method of manufacturing the same, the organic encapsulation layer 152 and the edge line pattern 160 are integrated with each other, and overflow of the liquid material may be prevented without a separate dam structure, thereby minimizing the non-active area NA and maximizing the effective area of the light emitting display device.

Meanwhile, in the method of manufacturing the light emitting display device according to the present disclosure, when the edge line pattern 165 and the organic encapsulation layer 152 are made of different materials, the UV curing process of FIG. 8B may be omitted, and the organic material 1650 for forming the edge line pattern and the organic material 1520 for forming the organic encapsulation layer may be cured at once in the curing process of FIG. 8D, whereby the edge line pattern 165 and the organic encapsulation layer 152 may be formed simultaneously. As such, the organic encapsulation layer 152 and the edge line pattern 165 made of the material different therefrom may be observed at the edge portion of the completed light emitting display device.

In the light emitting display device according to the present disclosure and the method of manufacturing the same, the control metal pattern 155 positioned at the edge line of the organic encapsulation layer 152 is formed of a getter material that captures oxygen and water, and thus is left behind in the light emitting display device, prevents outside air and water from entering the inside of the light emitting display device from the lateral side, and stabilizes operation of the active area by capturing water or hydrogen generated from the light emitting display device in the edge portion.

In the light emitting display device according to the present disclosure and the method of manufacturing the same, the control metal pattern 155 may be located on the first inorganic encapsulation layer 151 while overlapping the gate driver or the metal line 127, and a dam pattern spaced apart from the organic encapsulation layer 152 on the control metal pattern 155 may be omitted, thus obviating an organic protrusion structure spaced apart from the organic encapsulation layer 152 outside, thereby optimizing the effective area of the substrate. Accordingly, a narrow bezel of the light emitting display device may be realized.

In the light emitting display device according to the present disclosure and the method of manufacturing the same, the control metal pattern 155 is formed of a metal having water and gas capturing capability, and the use of harmful substances is prevented. Accordingly, there is exhibited an ESG (environment/social/governance) effect in view of eco-friendliness and process optimization.

A light emitting display device according to one or more aspects of the present disclosure may comprise a substrate having an active area comprising a plurality of sub-pixels and a non-active area surrounding the active area, a light emitting device at each of the plurality of sub-pixels, a first inorganic encapsulation layer to cover the light emitting device, the first inorganic encapsulation layer provided at the active area and the non-active area, a control metal pattern to surround the active area at the non-active area, the control metal pattern on the first inorganic encapsulation layer, an edge line pattern on the control metal pattern, the edge line pattern comprising an organic material, an organic encapsulation layer on the first inorganic encapsulation layer in an area inward from the control metal pattern and a second inorganic encapsulation layer to cover the organic encapsulation layer and the edge line pattern and provided to extend outward from the edge line pattern.

In a light emitting display device according to one or more aspects of the present disclosure, the edge line pattern may be integral with the organic encapsulation layer.

In a light emitting display device according to one or more aspects of the present disclosure, the edge line pattern may be made of a material same as the organic encapsulation layer.

In a light emitting display device according to one or more aspects of the present disclosure, the edge line pattern may be made of an organic material different from the organic encapsulation layer.

In a light emitting display device according to one or more aspects of the present disclosure, the control metal pattern may comprise a getter metal.

In a light emitting display device according to one or more aspects of the present disclosure, the control metal pattern may comprise at least one selected from among cerium, lanthanum, magnesium, barium, aluminum, and titanium.

In a light emitting display device according to one or more aspects of the present disclosure, the edge line pattern may be thicker than the control metal pattern, and the control metal pattern has high surface roughness relative to the first inorganic encapsulation layer.

In a light emitting display device according to one or more aspects of the present disclosure, the control metal pattern may have a closed loop shape surrounding the active area.

In a light emitting display device according to one or more aspects of the present disclosure, the control metal pattern may have a loop shape surrounding the active area and has an opening in at least one side thereof.

In a light emitting display device according to one or more aspects of the present disclosure, each of the sub-pixels may further comprise a thin film transistor connected to the light emitting device. The control metal pattern may overlap a line provided at the non-active area, and the line at the non-active area may be located at a same layer as at least one metal constituting the thin film transistor.

In a light emitting display device according to one or more aspects of the present disclosure, a passivation film and the first inorganic encapsulation layer may be provided between the line at the non-active area and the control metal pattern.

In a light emitting display device according to one or more aspects of the present disclosure, the control metal pattern may be provided over a flat portion and protrusions adjacent to the flat portion at the non-active area. A lower part of the edge line pattern may be provided at a space between the flat portion and the protrusions and an upper part of the edge line is in contact with the organic encapsulation layer.

In a light emitting display device according to one or more aspects of the present disclosure, each of the protrusions may comprise at least one layer among a planarization film and a bank.

A light emitting display device according to one or more aspects of the present disclosure may further comprise touch electrodes on the second inorganic encapsulation layer corresponding to the active area.

A method of manufacturing a light emitting display device according to one or more aspects of the present disclosure may comprise preparing a substrate having an active area comprising a plurality of sub-pixels and a non-active area surrounding the active area, forming a light emitting device at each of the plurality of sub-pixels, forming a first inorganic encapsulation layer covering the light emitting device at the active area and the non-active area, forming a control metal pattern surrounding the active area at the non-active area on the first inorganic encapsulation layer, forming an edge line pattern on the control metal pattern, forming an organic encapsulation layer on the first inorganic encapsulation layer in an area inward from the control metal pattern and forming a second inorganic encapsulation layer covering the organic encapsulation layer and the edge line pattern to extend outward from the edge line pattern.

In a method of manufacturing a light emitting display device according to one or more aspects of the present disclosure, forming the edge line pattern may be performed in a manner in which a liquid organic material is applied on the control metal pattern and then cured by light irradiation.

In a method of manufacturing a light emitting display device according to one or more aspects of the present disclosure, forming the organic encapsulation layer may be performed in a manner in which a liquid organic encapsulation material is applied, cured by light irradiation, and integrated with the edge line pattern.

In a method of manufacturing a light emitting display device according to one or more aspects of the present disclosure, the organic encapsulation layer and the edge line pattern may be simultaneously irradiated with light.

As is apparent from the above description, according to aspects of the present disclosure, a light emitting display device and a method of manufacturing the same have the following effects.

First, in the light emitting display device according to the present disclosure, before application of a liquid organic encapsulation material, a control metal pattern is provided and an edge line pattern is formed on the control metal pattern, thus guiding an organic encapsulation layer inward from the edge line pattern during application of the liquid organic encapsulation material.

Second, the organic encapsulation layer and the edge line pattern are integrally formed with each other, and overflow of the liquid material may be prevented without a separate dam structure, thereby minimizing the outer area and maximizing the effective area of the light emitting display device.

Third, the control metal pattern located at the edge line of the organic encapsulation layer is a metal pattern that captures oxygen and water, thus preventing outside air and water from entering the inside of the light emitting display device from the lateral side, and also it is possible to stabilize operation of the active area by capturing water or hydrogen generated from the light emitting display device in the edge portion.

Fourth, the control metal pattern may be positioned on an inorganic encapsulation layer while overlapping a gate driver or a line, and a dam pattern spaced apart from the organic encapsulation layer on the control metal pattern may be omitted, thus obviating an organic protrusion structure spaced from the organic encapsulation layer outside, thereby realizing a narrow bezel.

Fifth, in the light emitting display device according to the present disclosure, the control metal pattern is formed of a metal having water and gas capturing capability, the use of harmful substances may be prevented, and the effective area of the substrate may be optimized. Accordingly, there is exhibited an ESG (environment/social/governance) effect in view of eco-friendliness and process optimization.

It will be apparent to those skilled in the art that various modifications and variations can be made in the light emitting display device and the method of manufacturing the same of the present disclosure without departing from the spirit or scope of the aspects of the present disclosure. Thus, it is intended that the present disclosure covers the modifications and variations of the aspects provided they come within the scope of the appended claims and their equivalents.

What is claimed is:

1. A light emitting display device, comprising:
a substrate having an active area comprising a plurality of sub-pixels and a non-active area surrounding the active area;
a light emitting device disposed at each of the plurality of sub-pixels;
a first inorganic encapsulation layer covering the light emitting device, the first inorganic encapsulation layer provided at the active area and the non-active area;
a control metal pattern surrounding the active area at the non-active area, the control metal pattern disposed on the first inorganic encapsulation layer;
an edge line pattern disposed on the control metal pattern, the edge line pattern comprising an organic material;
an organic encapsulation layer disposed on the first inorganic encapsulation layer in an area inward from the control metal pattern; and
a second inorganic encapsulation layer covering the organic encapsulation layer and the edge line pattern and provided to extend outward from the edge line pattern.

2. The light emitting display device according to claim 1, wherein the edge line pattern is integral with the organic encapsulation layer.

3. The light emitting display device according to claim 1, wherein the edge line pattern is made of a material same as the organic encapsulation layer.

4. The light emitting display device according to claim 1, wherein the edge line pattern is made of an organic material different from the organic encapsulation layer.

5. The light emitting display device according to claim 1, wherein the control metal pattern comprises a getter metal.

6. The light emitting display device according to claim 1, wherein the control metal pattern includes one of cerium, lanthanum, magnesium, barium, aluminum, and titanium.

7. The light emitting display device according to claim 1, wherein the edge line pattern is thicker than the control metal pattern, and the control metal pattern has high surface roughness relative to the first inorganic encapsulation layer.

8. The light emitting display device according to claim 1, wherein the control metal pattern has a closed loop shape surrounding the active area.

9. The light emitting display device according to claim 1, wherein the control metal pattern has a loop shape surrounding the active area and has an opening in at least one side thereof.

10. The light emitting display device according to claim 1, wherein each of the sub-pixels further comprises a thin film transistor connected to the light emitting device, the control metal pattern overlaps a line provided at the non-active area, and the line at the non-active area is located at a same layer as at least one metal constituting the thin film transistor.

11. The light emitting display device according to claim 10, wherein a passivation film and the first inorganic encapsulation layer are provided between the line at the non-active area and the control metal pattern.

12. The light emitting display device according to claim 1, wherein the control metal pattern is provided over a flat portion and protrusions adjacent to the flat portion at the non-active area, and
wherein a lower part of the edge line pattern is provided at a space between the flat portion and the protrusions and an upper part of the edge line is in contact with the organic encapsulation layer.

13. The light emitting display device according to claim 12, wherein each of the protrusions comprises at least one layer among a planarization film and a bank.

14. The light emitting display device according to claim 1, further comprising touch electrodes disposed on the second inorganic encapsulation layer corresponding to the active area.

15. A method of manufacturing a light emitting display device, comprising:
preparing a substrate having an active area comprising a plurality of sub-pixels and a non-active area surrounding the active area;
forming a light emitting device at each of the plurality of sub-pixels;
forming a first inorganic encapsulation layer covering the light emitting device at the active area and the non-active area;
forming a control metal pattern surrounding the active area at the non-active area on the first inorganic encapsulation layer;
forming an edge line pattern on the control metal pattern;
forming an organic encapsulation layer on the first inorganic encapsulation layer in an area inward from the control metal pattern; and
forming a second inorganic encapsulation layer covering the organic encapsulation layer and the edge line pattern to extend outward from the edge line pattern.

16. The method according to claim 15, wherein forming the edge line pattern is performed in a manner in which a liquid organic material is applied on the control metal pattern and then cured by light irradiation.

17. The method according to claim 15, wherein forming the organic encapsulation layer is performed in a manner in which a liquid organic encapsulation material is applied, cured by light irradiation, and integrated with the edge line pattern.

18. The method according to claim 15, wherein the organic encapsulation layer and the edge line pattern are simultaneously irradiated with light.
